(19) United States
(12) Patent Application Publication
(10) Pub. No.: US 2013/0009128 A1
(43) Pub. Date: Jan. 10, 2013

(54) NANOSCALE SWITCHING DEVICE

(76) Inventors: Gilberto Ribeiro, Menlo Park, CA (US); Janice H Nickel, Sunnyvale, CA (US); Jianhua YA Yang, Palo Alto, CA (US)

(21) Appl. No.: 13/384,820

(22) PCT Filed: Mar. 31, 2010
(86) PCT No.: PCT/US10/29423

§ 371 Date: Jan. 19, 2012

(51) Int. Cl. H01L 29/06; H01L 21/34

(52) U.S. Cl. 257/9; 438/104; 257/E29.024; 257/E21.459

(57) ABSTRACT

A nanoscale switching device has an active region containing a switching material. The switching device has a first electrode and a second electrode with nanoscale widths, and the active region is disposed between the first and second electrodes. A protective cladding layer surrounds the active region. The protective cladding layer is formed of a cladding material unreactive to the switching material. An interlayer isolation layer formed of a dielectric material is disposed between the first and second electrodes and outside the protective cladding layer.

### BACKGROUND

Significant research and development efforts are currently directed towards designing and manufacturing nanoscale electronic devices, such as nanoscale memories. Nanoscale electronics promises significant advances, including significantly reduced features sizes and the potential for self-assembly and for other relatively inexpensive, non-photolithography-based fabrication methods. However, the design and manufacture of nanoscale electronic devices present many new challenges.

For instance, nanoscale devices using switching materials such as titanium oxide that show resistive switching behavior have recently been reported. The switching behavior of such devices has been linked to the memristor circuit element theory originally predicted in 1971 by L. O. Chua. The discovery of the memristive behavior in the nanoscale switches has generated significant interests, and there are substantial on-going research efforts to further develop such nanoscale switches and to implement them in various applications. One of the many important potential applications is to use such switching devices as memory units to store digital data. A memory device may be constructed as an array of such switching devices in a crossbar configuration to provide a very high device density. There are, however, technical challenges that have to be addressed in order to make the switching devices useful for actual applications. One significant issue is how to maintain the switching characteristics of the switching devices over multiple ON/OFF cycles to provide a reasonably long operation life.

### BRIEF DESCRIPTION OF THE DRAWINGS

Some embodiments of the invention are described, by way of example, with respect to the following figures:

FIG. 1 is a schematic perspective view of a nanoscale switching device having a protective cladding layer in accordance with an embodiment of the invention;

FIG. 2 is a schematic cross-sectional view of the nanoscale switching device of FIG. 1;

FIG. 3 is a flow chart showing a method of an embodiment of the invention for making the nanoscale switching device with a protective cladding layer;

FIGS. 4A-4F are schematic cross-sectional views showing the formation of layers on a substrate corresponding to steps of the method of FIG. 3;

FIG. 5 is a schematic perspective view of a crossbar array of nanoscale switching devices each having a protective cladding layer.

### DETAILED DESCRIPTION

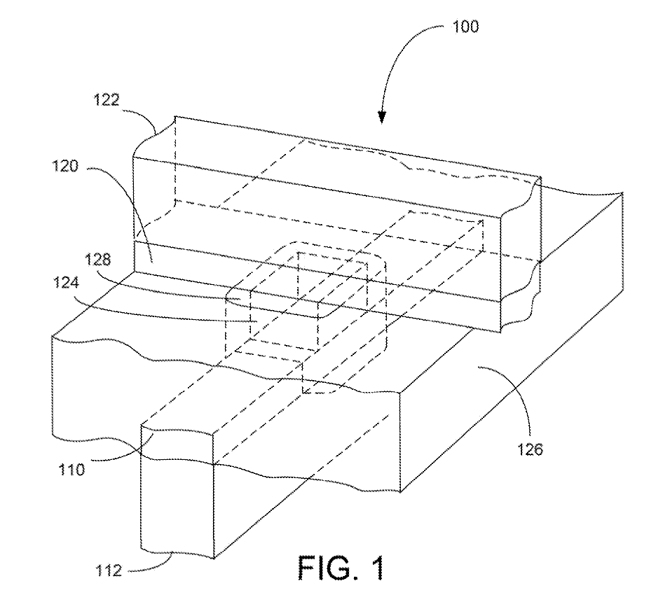

FIG. 1 shows a nanoscale switching device 100 in accordance with an embodiment of the invention. The switching device 100 comprises a bottom contact structure that includes a word line 112 and a bottom electrode 110, and a top contact structure that includes a top electrode 120 and a bit line 122. Disposed between the top and bottom electrode 120 and 110 is an active region 124 that contains a switching material. As described in greater detail below, the switching material has electrical characteristics that can be controllably modified to allow the device to be switched to an ON state with a low-resistance value and an OFF state with a high-resistance value, or intermediate states between the ON and OFF states.

Each of the top and bottom electrodes 120 and 110 may have a width and on the nanoscale. As used hereinafter, the term “nanoscale” means the object has one or more dimensions smaller than one micrometer, and in some embodiments less than 500 nanometers and often less than 100 nanometers. For example, the electrodes 120 and 110 may have a width in the range of 5 nm to 500 nm. Likewise, the active region 124 may have a height that is on the nanoscale and typically from a few nanometers to tens of nanometers.

The word line 112, bit line 122, and electrodes 110 and 120 are electrically conductive but may be formed of different materials. In this embodiment, the word line 112 and bit line are for providing high conductivity or low resistance, and may be formed, for example, by a Cu damascene process or Al conductor process. The electrodes 110 and 120 may be formed of a conductive material selected to prevent the material of the word line 112 or bit line 122 from interacting with the switching material, and may be a metal such as platinum, gold, copper, tantalum, tungsten, etc., metallic compounds such as titanium nitride, tungsten nitride etc., or doped semiconductor materials. In some other embodiments, the electrodes 110 and 120 may provide sufficient conductance and the word line 112 and bit line 122 may not be necessary.

In the embodiment shown in FIG. 1, the top electrode 120 extends at an angle to the bottom electrode 110. The angle may be, for example, around 90 degrees, but may be of other values depending on the device design. As the top and bottom electrodes 120 and 110 are on different height levels, and the active region 124 occupies generally only the area of overlap between the electrodes, structural support is needed for the top electrode 120. To that end, the space under the top electrode 120 and outside the active region 124 may be largely filled with a dielectric material to form an interlayer dielectric layer 126. The interlayer dielectric layer 126 provides structural support and also electrically insulates the electrodes 120 and 110. It also isolates the switching device from any adjacent switching devices.

In accordance with a feature of embodiments of the invention, the nanoscale switching device 100 has a protective cladding layer 128. The protective cladding layer 128 surrounds the active region 124 and extends in height between at least the top and bottom electrodes 120 and 110, and thus shields or isolates the switching material in the active region 124 from the interlayer dielectric layer 126. As described in greater detail below, the protective cladding layer 128 is substantially impervious to dopants in the switching material in the active region 124. As a result, the protective cladding layer 128 prevents the switching material from losing or gaining dopants due to diffusion into or reaction with the dielectric material of the interlay dielectric layer 126.

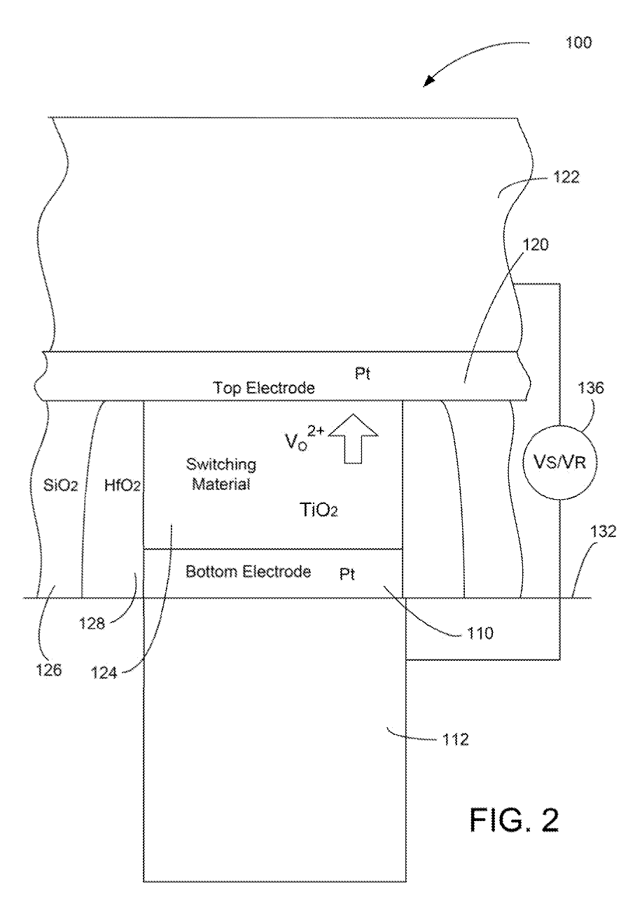

To facilitate a better understanding of the issues addressed by the invention, the components and operation principles of the switching device 100 in one embodiment are described with reference to FIG. 2. As shown in FIG. 2, the active region 124 disposed between the top electrode 120 and bottom electrode 110 contains a switching material. The switching material is capable of carrying a species of mobile ionic dopants such that the dopants can be controllably transported through the switching material and redistributed to change the electrical properties of either the switching material or the interface of the switching material and an electrode, which in the illustrated example of FIG. 2 may be the top electrode 120. This ability to change the electrical properties as a function of dopant distribution allows the switching device 100 to be placed in different switching states by applying a switching voltage from a voltage source 136 to the electrodes 120 and 110.

Generally, the switching material may be electronically semiconducting or nominally insulating and a weak ionic conductor. Many different materials with their respective suitable dopants can be used as the switching material. Materials that exhibit suitable properties for switching include oxides, sulfides, selenides, nitrides, carbides, phosphides, arsenides, chlorides, and bromides of transition and rare earth metals. Suitable switching materials also include elemental semiconductors such as Si and Ge, and compound semiconductors such as III-V and II-VI compound semiconductors. The III-V semiconductors include, for instance, BN, BP, BSb, AlP, AlSb, GaAs, GaP, GaN, InN, InP, InAs, and InSb, and ternary and quaternary compounds. The II-VI compound semiconductors include, for instance, CdSe, CdS, CdTe, ZnSe, ZnS, ZnO, and ternary compounds. The II-VI compound switching materials may also include phase change materials. The switching materials may also include filament structures such as a-Si:Ag that has Ag filaments in an a-Si matrix. These listings of possible switching materials are not exhaustive and do not restrict the scope of the present invention.

The dopant species used to alter the electrical properties of the switching material depends on the particular type of switching material chosen, and may be cations, anions or vacancies, or impurities as electron donors or acceptors. For instance, in the case of a transition metal oxide such as TiO₂, the dopant species may be oxygen vacancies (V_{O}²⁺). For GaN, the dopant species may be nitride vacancies or sulfide ion dopants. For compound semiconductors, the dopants may be n-type or p-type impurities or metal filamentary inclusions.

By way of example, as illustrated in FIG. 2, the switching material may be TiO₂, and the dopants may be oxygen vacancies (V_{O}²⁺). When a DC switching voltage from the voltage source 136 is applied to the top and bottom electrodes 120 and 110, an electric field is created across the active region 124. This electric field, if of sufficient strength and proper polarity, may drive the oxygen vacancies to drift through the switching material in the active region 124 towards the top electrode 120, thereby turning the device into an ON state.

If the polarity of the electric field is reversed, the oxygen vacancies may drift in an opposite direction across the active region 124 and away from the top electrode 120, thereby turning the device into an OFF state. In this way, the switching is reversible and may be repeated. Due to the relatively large electric field needed to cause dopant drifting, after the switching voltage is removed, the locations of the dopants remain stable in the switching material. In other words, the switching may be non-volatile.

The state of the switching device 100 may be read by applying a read voltage from the voltage source 136 to the top and bottom electrodes 120 and 110 to sense the resistance across these two electrodes. The read voltage is typically much lower than the switching voltage required to cause drifting of the ionic dopants in the active region 124, so that the read operation does not alter the ON/OFF state of the switching device.

The switching behavior described above may be based on different mechanisms. In one mechanism, the switching behavior may be an “interface” phenomenon. For instance, in the illustrated example of FIG. 2, initially, with a low concentration of oxygen vacancies in the TiO₂ switching material near the top electrode 120, the interface of the switching material and the top electrode 120 may behave like a Schottky barrier, with an electronic barrier that is difficult for electrons to go through. Similarly, the interface of the switching material and the bottom electrode 110 may also behave like a Schottky barrier, with a flow direction opposite to that of the Schottky-like barrier at the top electrode 120. As a result, the device has a relatively high resistance in either flow direction. When a switching voltage is applied to the top and bottom electrodes 120 and 110 to turn the device ON, with the top electrode as the negative side, the oxygen vacancies drift towards the top electrodes 120. The increased concentration of dopants near the top electrode 120 changes the electrical property of the interface from one like a Schottky barrier to one like an Ohmic contact, with a significantly reduced electronic barrier height or width. As a result, electrons can tunnel through the interface much more easily, and the switching device 100 is now in the ON state with a significantly reduced overall resistance for a current flowing from the bottom electrode 110 to the top electrode 120.

In another mechanism, the reduction of the resistance of the active region 124 may be a “bulk” property of the switching material. The redistribution of the dopant level in the switching material causes the resistance across the switching material to fall, and this may account for the decrease of the resistance of the device between the top and bottom electrodes 120 and 110. It is also possible that the resistance change is the result of a combination of both the bulk and interface mechanisms. Even though there may be different mechanisms for explaining the switching behavior, it should be noted that the present invention does not rely on or depend on any particular mechanism for validation, and the scope of the invention is not restricted by which switching mechanism is actually at work.

As can be seen from the above description, the redistribution of dopants in the switching material in the active region may be responsible for the switching behavior of the switching device. If the amount of dopants in the active region is altered in an unintended way, the switching characteristics of the device may be changed uncontrollably. One possible mechanism for undesired dopant amount alteration is the diffusion of the dopants from the switching material into the surrounding materials or the reaction of the switching material or the dopants with the surrounding materials. It has been observed by the inventors that when a transition metal oxide, such as TiO₂, is used as the switching material, a substantial change in the amount of oxygen vacancies can occur over time if the switching material is in direct contact with the interlayer dielectric layer, which is typically formed of silicon oxide, silicon nitride, or silicon carbon nitride. Due to the small volume of the switching material in the active region of the switching device and the relatively low concentration of the dopants, even a small amount of dopant loss (or gain) can have significant impacts on the switching characteristics of the device. The device may even lose its ability to switch if the dopant amount is changed too much, or the edge of the device may be made conducting by the change in the dopant, amount at the edge.

This problem of dopant change is effectively solved by the inclusion of the protective cladding layer 128 in the nanoscale switching device 100. In the embodiment shown in FIG. 1, the cladding layer 128 surrounds the active region 124 and extends in height from at least the bottom electrode 110 to the top electrode 120. In this way, the protective cladding layer isolates or shields the active region 124 from the interlayer dielectric layer 126, and prevents the switching material from contacting and/or chemically interacting with the dielectric material of the interlayer dielectric layer. The protective cladding layer may be formed of a non-conducting cladding material that is chemically stable and unreactive to the switching material, and substantially impervious to the dopants in the switching material. As used herein, the term “impervious” means that the dopants cannot migrate through the cladding material under normal operating conditions. In this regard, the interlayer dielectric typically is selected to have a low dielectric constant so that the capacitance of the device will be low to allow a faster access time. Such dielectric materials, however, may have the tendency to chemically interact with the switching material. The cladding material, in contrast, is selected to be substantially chemically inert. Thus, the dopants in the switching material are confined in the active region 124 and cannot be lost or gained through the protective cladding layer 128.

By way of example, when the switching material is TiO₂, the dopants are oxygen vacancies. The cladding material in this case may be hafnium oxide (HfO₂), which is a thermodynamically more stable oxide and thus is effective in preventing oxygen vacancies or oxygen from moving away from the TiO₂ switching material. Other examples of usable cladding materials include Zirconium oxide (ZrO₂), Magnesium oxide (MgO), Calcium oxide (CaO), Aluminum oxide (Al₂O₃) etc. In contrast, the dielectric material forming the interlayer dielectric layer is different from the cladding material and may be, for example, an oxide, nitride, or carbide, such; as silicon oxide (SiO₂), silicon nitride (Si₃N₄), silicon carbon nitride (SiCₓN_{y}), etc.

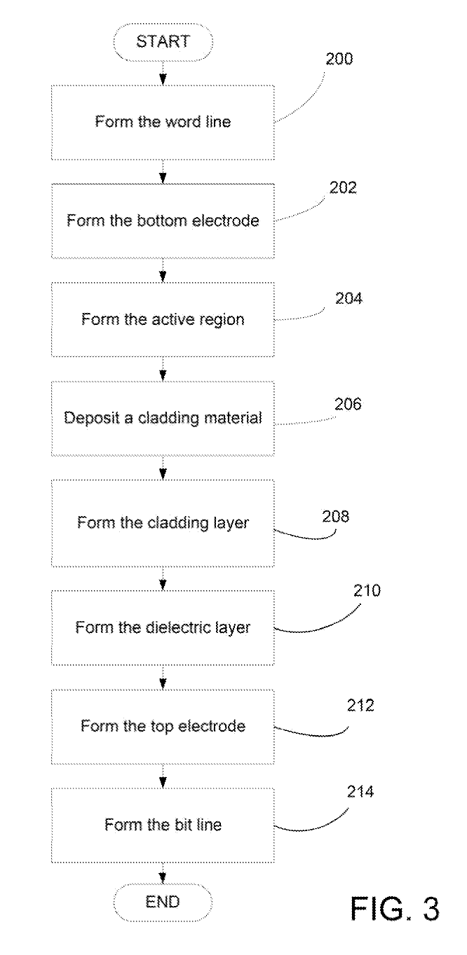

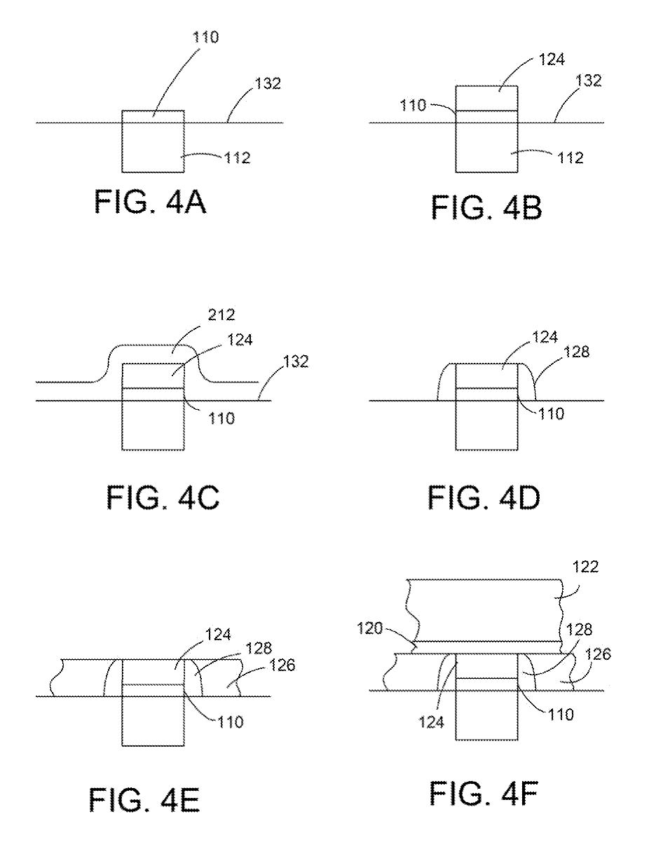

FIG. 3 shows a method of an embodiment of the invention for forming the nanoscale switching device with a protective cladding layer. This method is described in conjunction with FIGS. 4A-4F, which illustrate the evolution of the device stack structure resulting from the steps of the method in FIG. 3. First, the word line 112 is formed in the substrate 132 (step 200), and the bottom electrode 110 is formed over the word line 112 (step 202), as shown in FIG. 4A. The bottom electrode 100 may be an elongated structure, but only its width is seen in the cross-sectional view of FIG. 4A. A layer of a switching material is then deposited on the bottom electrode 110 and formed into the active region (step 204), as shown in FIG. 4B. The active region may have a generally rectangular or square shape, or circular or oval shape. This step of forming the active region may include first deposing a layer of switching material over the entire substrate and covering the bottom electrode, and then patterning the active region using a photoresist and etching away the switching material outside the patterned active region.

A layer 212 of cladding material is then deposited onto the substrate to cover the active region 124 and the bottom electrode 110 (step 206), as shown in FIG. 4C. An anisotropic etch process is then used to etch away the cladding material covering the active region 124 and most of the substrate, but leaving a ring of cladding material surrounding the active region, thereby forming the protective cladding layer 128 (step 208). The resultant structure is shown in FIG. 4D. A layer of dielectric material is then deposited over the structure of FIG. 4D, and an electro-chemical planarizing (CMP) process is used to flatten the dielectric layer 126 and to expose the top of the active region 124 (step 210), as shown in FIG. 4E. A top electrode 120 is then formed over the active region 124 and the interlayer dielectric layer 126 (step 212), and a bit line 122 in the form of a relatively thick conductive layer is formed over the top electrode 120 (step 214), as shown in FIG. 4F. This step may include depositing a layer of electrode material over the active region and the dielectric layer, patterning the top electrode, and etching away excess electrode material to form the top electrode 120. The method of FIG. 3 described above is only an example of how to form a switching device with the cladding layer, and other methods may be used to form such a structure.

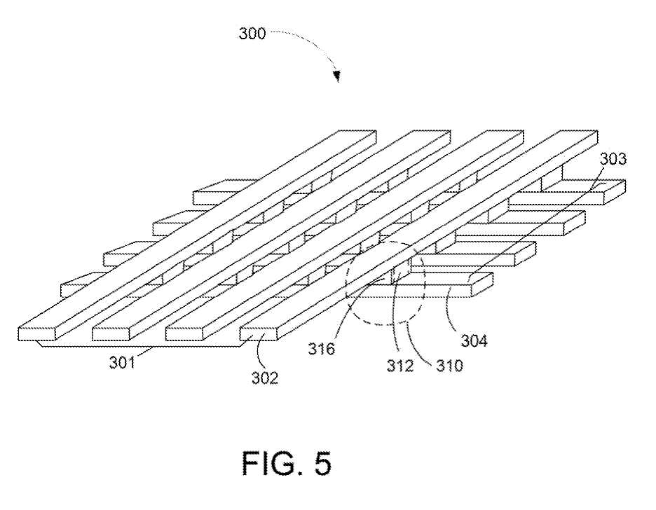

Multiple nanoscale switching devices, each with a protective cladding layer, may be formed into a crossbar array for various applications. FIG. 5 shows an example of a two-dimensional array 300 of such switching devices. The array has a first, group 301 of generally parallel nanowires 302 in a top layer, and a second group 303 of generally parallel nanowires 304 in a bottom layer. The nanowires 302 in the first group 301 run in a first direction, and the nanowires 304 in the second group 303 run in a second direction at an angle, such as 90 degrees, from the first direction. The two layers of nanowires form a two-dimensional crossbar structure, with each nanowire 302 in the top layer intersecting a plurality of the nanowires 304 of the bottom layer. A nanoscale switching device 310 may be formed at each intersection of the nanowires in this crossbar structure. The switching device 310 has a nanowire 302 of the first group 301 as its top electrode, and a nanowire 304 of the second group 303 as its bottom electrode. An active region 312 containing a switching material is disposed between the top and bottom nanowires 302 and 304, and a protective cladding layer 316 is formed around the active region. The space between the top and bottom layers outside the cladding layer 316 of the nanoscale switching device 310 may be filled with a dielectric material to form an interlayer dielectric layer, which for clarity of illustration is not explicitly shown in FIG. 5. The cladding material forming the protective cladding layer 316 is different from the dielectric material of the interlayer dielectric layer in that it is unreactive to the switching materials and impervious to the dopants of switching material. Thus, the protective cladding layer 316 prevents the loss of dopants from the switching material of the switching device 310 due to diffusion into or reaction with the dielectric material of the interlayer dielectric layer.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A nanoscale switching device comprising:
a first electrode of a nanoscale width;
a second electrode of a nanoscale width;
an active region disposed between the first and second electrodes, the active region containing a switching material;
a protective cladding layer surrounding at least the active region and formed of a cladding material unreactive to the switching material; and
an interlayer dielectric layer formed of a dielectric material and disposed between the first and second electrodes outside the protective cladding layer.

2. A nanoscale switching device as in claim 1, wherein the switching material is capable of carrying a species of dopants and transporting the dopants under an electric field.

3. A nanoscale switching device as in claim 3, wherein the cladding material is impervious to the dopants in the switching material.

4. A nanoscale switching device as in claim 2, wherein the cladding material is a metal oxide.

5. A nanoscale switching device as in claim 4, wherein the cladding material is selected from the group of hafnium oxide, zirconium oxide, magnesium oxide, calcium oxide and aluminum oxide.

6. A nanoscale switching device as in claim 1, wherein the dielectric material is an oxide, a carbide, a nitride, or combination thereof.

7. A nanoscale crossbar array comprising:
a first group of conductive nanowires running in a first direction;
a second group of conductive nanowires running in a second direction and intersecting the first group of nanowires;
a plurality of switching devices formed at intersections of the first group of nanowires with the second group of nanowires, each switching device having a first electrode formed by a first nanowire of the first group and a second electrode formed by a second nanowire of the second group, an active region disposed at the intersection between the first and second electrodes, a protective cladding layer surrounding the active region, and an interlayer dielectric layer of a dielectric material disposed between the first and second groups of nanowires outside the protective cladding layer, the active region comprising a switching material, the protective cladding layer being formed of a cladding material unreactive to the switching material.

8. A nanoscale switching device as in claim 7, wherein the switching material is capable of carrying a species of dopants and transporting the dopants under an electric field.

9. A nanoscale switching device as in claim 8, wherein the cladding material is impervious to the dopants of the switching material.

10. A nanoscale switching device as in claim 8, wherein the cladding material is a metal oxide.

11. A nanoscale switching device as in claim 10, wherein the cladding material is selected from the group of hafnium oxide, zirconium oxide, magnesium oxide, calcium oxide and aluminum oxide.

12. A nanoscale switching device as in claim 8, wherein the dielectric material is an oxide, a carbide, a nitride, or combination thereof.

13. A method of forming a nanoscale switching device, comprising:
forming a first electrode of a nanoscale width and a second electrode of a nanoscale width;
forming an active region between the first and second electrodes, the active region comprising a switching material capable of carrying a species of dopants and transporting the dopants under an electric field;
forming a protective cladding layer surrounding the active region, the protective cladding layer being formed of a cladding material unreactive to the switching material and impervious to the dopants in the switching material; and
forming an interlayer dielectric layer of a dielectric material outside the protective cladding layer.

14. A method of forming a nanoscale switching device as in claim 13, wherein the switching material is a first metal oxide, and the cladding material is a second metal oxide.

15. A method of forming a nanoscale switching device as in claim 13, wherein the step of forming the protective cladding layer includes depositing the cladding material over the active region and the first electrode and applying anisotropic etching to the deposited cladding material to form the protective cladding layer surrounding the active region.
